(19) United States
(12) Patent Application Publication
(10) Pub. No.: US 2007/0108518 A1
(43) Pub. Date: May 17, 2007

(54) SEMICONDUCTOR DEVICE

(75) Inventors: Koichi ENDO, Suginami-ku (JP); Kumiko SATO, Yokohama-shi (JP); Kiminori WATANABE, Kawasaki-shi (JP); Norio YASUHARA, Kawasaki-shi (JP); Tomoko MATSUDAI, Shibuya-ku (JP); Yusuke KAWAGUCHI, Miura-gun (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/420,148

(22) Filed: May 24, 2006

(30) Foreign Application Priority Data
Nov. 16, 2005 (JP) 2005-331742

(51) Int. Cl. H01L 29/76

(52) U.S. Cl. 257/339

(57) ABSTRACT

A gate electrode is formed on a gate insulator above a semiconductor substrate. Diffused regions are formed in a surface of the semiconductor substrate as sandwiching the gate electrode therebetween. A high-resistance layer is formed in the surface of the semiconductor substrate as electrically connected to the diffused region. A low-resistance layer is formed in the surface of the semiconductor substrate as electrically connected to the high-resistance layer. A drain electrode is connected to the low-resistance layer.

### CROSS REFERENCE TO RELATED APPLICATION

This application is based on and claims the benefit of priority from prior Japanese Patent Application No. 2005-331742, filed on Nov. 16, 2005, the entire contents of which are incorporated herein by reference.

### BACKGROUND OF THE INVENTION

1. Field of the Invention

The present invention relates to a semiconductor element, and more particularly to a semiconductor device including planar insulated-gate semiconductor elements.

2. Description of the Related Art

A conventional semiconductor device may comprise insulated-gate semiconductor elements such as MOS transistors, which are known to have such a structure that is referred to as a planar structure. In this planar structure, source/drain diffused regions of a MOS transistor are formed in a surface of a semiconductor substrate or a well, and a gate electrode is formed via a gate insulator in the well surface as sandwiched between these diffused regions, for example.

When the planar-structured semiconductor element is used as a high-breakdown voltage power semiconductor element, the diffused region is formed to have a LDD (Lightly Doped Drain) structure for achievement of a high breakdown voltage. In this structure, the diffused region includes a high-concentration layer (low-resistance layer), which is higher in impurity concentration and connected to an electrode. It also includes a low-concentration layer (high-resistance layer), which is lower in impurity concentration than the high-concentration layer and formed to extend toward the gate electrode, and has a high resistivity. In this structure, the low-concentration layer is depleted to retain a high-breakdown voltage when the semiconductor element is brought out of conduction.

Such the LDD-structured semiconductor element causes the following problem when the gate electrode is silicided to reduce the gate resistance. Namely, the reduction in gate resistance requires formation of a silicide layer over a possibly wide area of the gate electrode surface, preferably over the entire surface, if possible. If the entire surface of the gate electrode is silicided, however, an adjacent LDD region may also be silicided possibly. Silicidation of the LDD region leads to a lowered breakdown voltage of the semiconductor element. The silicidation of the LDD region may be prevented if silicidation is executed after forming a mask material such as an oxide over the LDD region. Also in this case, however, the mask material must be formed with a margin more or less to prevent the silicidation of the LDD region. Accordingly, the mask material inevitably overlaps the gate electrode. In this case, part of the gate electrode is not silicided and still has a high-resistance portion, which prevents the gate resistance from lowering sufficiently. Thus, the conventional structure of the semiconductor element is makes it difficult to achieve a lowered gate resistance and an elevated breakdown voltage of the element at the same time.

### SUMMARY OF THE INVENTION

In one aspect the present invention provides a semiconductor device, comprising: a gate electrode formed via a gate insulator above a semiconductor region; a first diffused region and a second diffused region both formed in a surface of the semiconductor region as sandwiching the gate electrode therebetween such that conduction is made between both diffused regions when a gate voltage is applied to the gate electrode; a third diffused region formed in the surface of the semiconductor region as electrically connected to the first diffused region and having a lower impurity concentration compared to the first diffused region; a fourth diffused region formed in the surface of the semiconductor region as electrically connected to the third diffused region and having a higher impurity concentration compared to the third diffused region; a first main electrode electrically connected to the fourth diffused region; and a second main electrode electrically connected to the second diffused region.

### BRIEF DESCRIPTION OF THE DRAWINGS

FIG. 1 shows a plan view of a semiconductor device according to a first embodiment of the present invention;

FIG. 2 shows a cross-sectional view taken along A-A′ in FIG. 1;

FIG. 3 shows operation of the semiconductor device of the first embodiment;

FIG. 4 illustrates a cross-sectional view of a LDD-structured high-breakdown voltage MOSFET as a comparative example;

FIG. 5 illustrates a cross-sectional view of an LDD-structured high-breakdown voltage MOSFET as a comparative example;

FIG. 6 shows a plan view of a semiconductor device according to a second embodiment of the present invention;

FIG. 7 shows a cross-sectional view taken along A-A′ in FIG. 6; and

FIG. 8 shows an alternative of the embodiment of the present invention.

### DETAILED DESCRIPTION OF THE INVENTION

Embodiments of the present invention will now be described with reference to the drawings.

[First Embodiment]

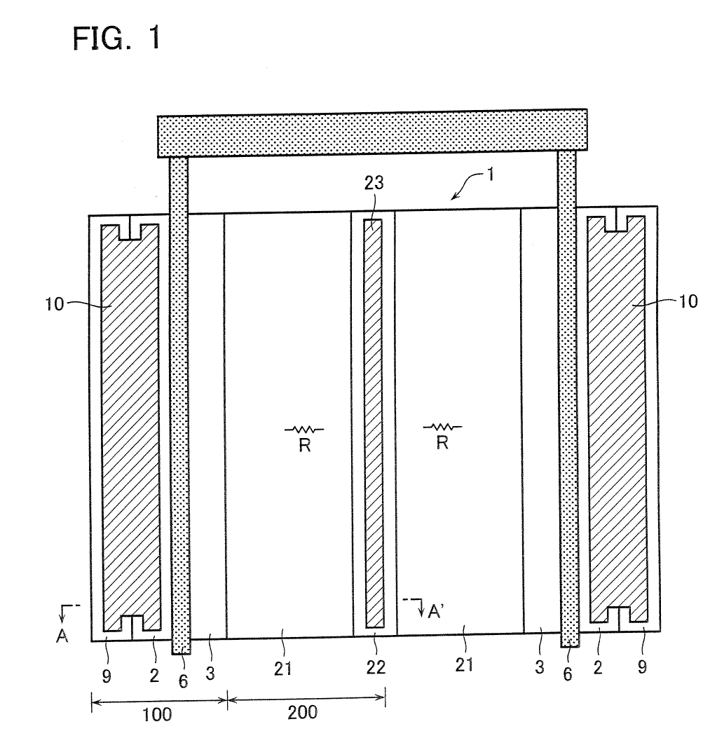

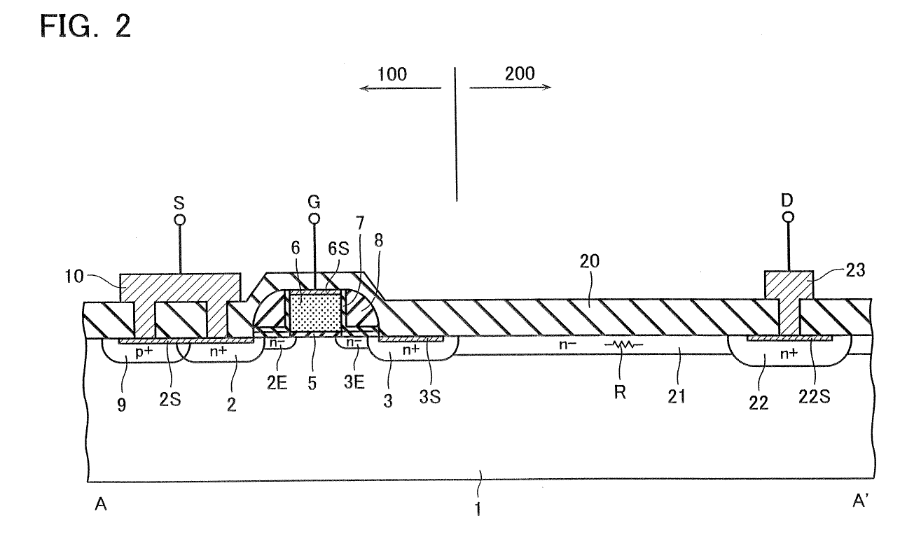

FIG. 1 shows a plan view of a semiconductor device according to a first embodiment of the present invention, and FIG. 2 shows a cross-sectional view taken along A-A′ in FIG. 1. This semiconductor device comprises a MOSFET 100, and a breakdown voltage sharing portion 200 arranged to share the breakdown voltage when the MOSFET 100 is brought out of conduction, which are formed on a semiconductor substrate 1 as shown in FIG. 2.

The MOSFET 100 includes an n⁺-type source diffused layer 2 (the second diffused region) and an n⁺-type drain diffused layer 3 (the first diffused region), which are formed in a surface of the p-type semiconductor substrate 1 as shown in FIG. 2. In the surface of the semiconductor substrate 1 sandwiched between the source diffused layer 2 and the drain diffused layer 3, a gate electrode 6 is formed using a material of polysilicon or the like on a gate insulator 5.

A silicide layer 6S is formed over the entire upper surface of the gate electrode 6 and connected to a gate wire, not shown. The source diffused layer 2 and the drain diffused layer 3 are provided with n⁻-type extension regions 2E, 3E that extend toward the gate electrode 6. The gate electrode 6 has a sidewall, which is provided with a silicon oxide film 7 and a silicon oxide film 8 thereon. The silicon oxide films 7 and 8 serve as a mask on self-aligned formation of the diffused layers 2, 3 by diffusion after formation of the extension regions 2E, 3E by diffusion. The surface of the drain diffused layer 3 is provided with a silicide layer 3S therein, which is formed together with the silicide layer 6S on formation of the silicide layer 6S.

A p⁺-type contact layer 9 is formed in the surface of the semiconductor substrate 1 at a position adjacent to the source diffused layer 2. The contact layer 9 and the source diffused layer 2 have surfaces, which are provided with a silicide layer 2S formed therein. Passing through an interlayer insulator 20 on the silicide layer 2S, a source electrode 10 is formed to short-circuit between the semiconductor substrate 1 and the source diffused layer 2.

On the other hand, the drain diffused layer 3 is provided with an n⁻-type high-resistance layer 21 (the third diffused region) and an n⁺-type contact layer 22 (the fourth diffused region),which extend away from the gate electrode 6. The contact layer 22 has a surface, which is provided with a silicide layer 22S formed therein. A drain electrode 23 is connected to the silicide layer 22S. The high-resistance layer 21 and the contact layer 22 form the breakdown voltage sharing portion 200.

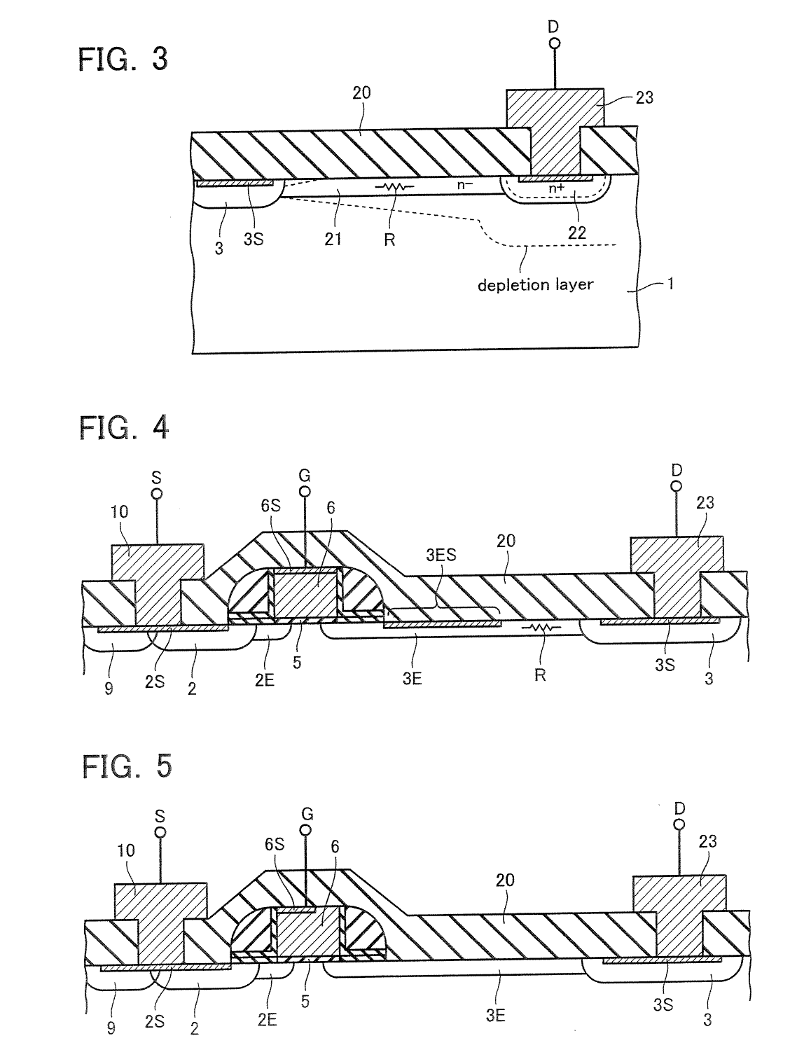

The high-resistance layer 21 has a lower impurity concentration compared to the drain diffused layer 3 or the like. Therefore, the high-resistance layer 21 can be depleted earlier than the drain diffused layer 3 and the contact layer 22 when the MOSFET 100 is brought out of conduction, and has a higher resistivity (see FIG. 3). Thus, the breakdown voltage sharing portion 200 can share much of the voltage applied across the drain electrode 23 and the source electrode 10 and correspondingly reduce the voltage applied to the MOSFET 100 at the time of out-of-conduction.

The silicide layers 2S, 6S, 3S and 22S are formed simultaneously by silicidation, with a mask material such as silicon nitride (not shown) formed with some margin. Specifically, the mask material is formed to cover the entire surface of the high-resistance layer 21 and cover part of the drain diffused layer 3 and the contact layer 22. In this case, a mask material such as silicon nitride (not shown) formed with some margin is used as a mask for silicidation. Therefore, the silicide layer 6S can be formed over the entire upper surface of the gate electrode 6. This makes it possible to minimize the gate resistance.

A problem associated with an LDD-structured high-breakdown voltage MOSFET is described with reference to FIGS. 4 and 5 as a comparative example, in which the parts common with the above embodiment are given the same reference numerals for omitting the detailed description thereof. In FIG. 4, the extension region 3E having a low impurity concentration and a high resistivity extends from the drain diffused region 3 toward the gate electrode 5. The drain electrode 23 is connected through the silicide layer 3S to the drain diffused region 3. In this structure, formation of the silicide layer 6S over the entire surface of the gate electrode 6 may also cause formation of a silicide layer 3ES in the extension region 3E due to misalignment of the mask material and the like (see FIG. 4). In this case, although the extension region 3E should have a resistivity retained high, it is given a lowered resistance, which may lower the breakdown voltage of the MOSFET possibly. For prevention of this problem, the margin of the mask material may be designed larger to form the silicide layer 6S only on part of the upper surface of the gate electrode 6 as shown in FIG. 5. In this case, however, the gate resistance can not be lowered sufficiently.

In this regard, the present embodiment further provides the breakdown voltage sharing portion 200 formed outside the drain diffused region 3 to prevent the breakdown voltage from lowering possibly even if the silicide layer 3S is formed in the drain diffused region 3. Accordingly, it is possible to form the silicide layer 6S over the entire upper surface of the gate electrode 6 to minimize the gate resistance without bringing a reduction in breakdown voltage.

In this embodiment, the MOSFET 100 and the breakdown voltage sharing portion 200 are formed laterally symmetrical about the drain electrode 23 as shown in FIG. 1 as a non-limiting example. Alternatively, the MOSFET 100 and the breakdown voltage sharing portion 200 may be formed only on one side. Otherwise, the MOSFET 100 and the breakdown voltage sharing portion 200 may be formed concentric about the drain electrode. In this way, the layout can be modified variously.

[Second Embodiment]

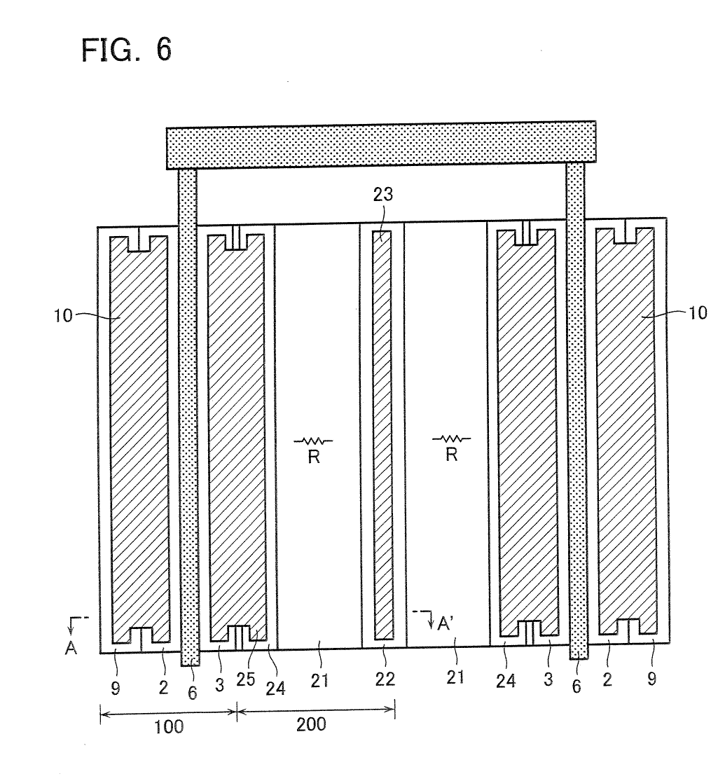

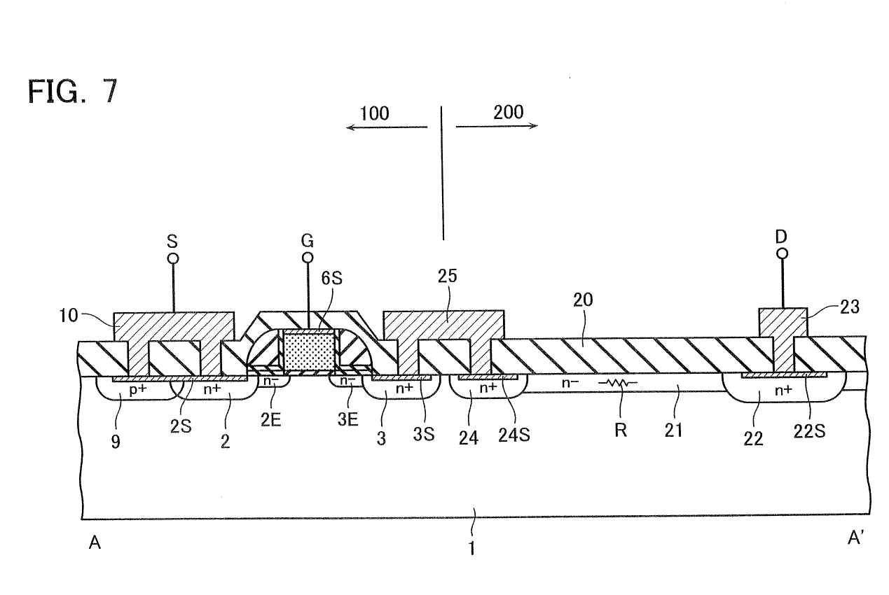

A second embodiment of the present invention is described next with reference to FIGS. 6 and 7. FIG. 6 shows a plan view of a semiconductor device according to this embodiment, and FIG. 7 shows a cross-sectional view taken along A-A′ in FIG. 6. The same configuring members as those in the first embodiment are given the same reference numerals for omitting the detailed description thereof.

In this embodiment the breakdown voltage sharing portion 200 further includes an n+-type low-resistance layer 24 (the fifth diffused region) provided between the drain diffused layer 3 and the high-resistance layer 21 as shown in FIG. 7, different from the first embodiment. The low-resistance layer 24 has a junction with the high-resistance layer 21 on the far side from the gate electrode 6. The low-resistance layer 24 is formed to locate the near side to the gate electrode 6 at a distance from the drain diffused layer 3 and, through a silicide layer 24S formed in the surface thereof, electrically connected to the drain diffused layer 3 using a wire 25. In this embodiment, a mask material is formed to cover the entire surface of the high-resistance layer 21, cover part of the low-resistance layer 24 and the contact layer 22, and cover the semiconductor substrate 1 located between the low-resistance layer 24 and the drain diffused layer 3. This mask material is employed as a mask for silicidation to form the silicide layers 2S, 3S, 6S, 22S at the same time. This configuration makes it possible to design the gate resistance in the MOSFET 100 and design the breakdown voltage in the breakdown voltage sharing portion 200 completely separately and accordingly facilitates the design of the semiconductor device having a desired characteristic.

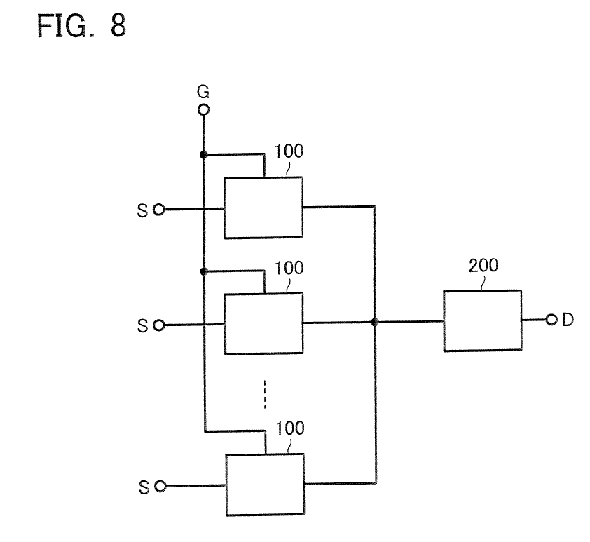

The embodiments of the invention are described above though the present invention is not limited to these embodiments but rather various modifications, alternatives and additions may be made without departing from the scope of the invention. For example, in the above embodiments, the semiconductor substrate is described as of p-type, and the source/drain diffused region as of n-type though p-type and n-type may be interchanged to configure the device, needless to say. An SOI substrate may be used as the semiconductor substrate 1. The present invention is also applicable to other insulated-gate semiconductor elements than the MOSFET, such as an IGBT and a Schottky barrier diode. In the above embodiments, one breakdown voltage sharing portion is provided per one MOSFET one by one in the configuration described above as a non-limiting example. Alternatively, a plurality of MOSFETs 100 can be connected through wires to a single breakdown voltage sharing portion 200 as shown in FIG. 8, for example, to reduce the number of the breakdown voltage sharing portion 200. This configuration is effective to reduce the size of the semiconductor device.

What is claimed is:

1. A semiconductor device, comprising:
a gate electrode formed via a gate insulator above a semiconductor region;
a first diffused region and a second diffused region both formed in a surface of said semiconductor region as sandwiching said gate electrode therebetween such that conduction is made between both diffused regions when a gate voltage is applied to said gate electrode;
a third diffused region formed in said surface of said semiconductor region as electrically connected to said first diffused region and having a lower impurity concentration compared to said first diffused region;
a fourth diffused region formed in said surface of said semiconductor region as electrically connected to said third diffused region and having a higher impurity concentration compared to said third diffused region;
a first main electrode electrically connected to said fourth diffused region; and
a second main electrode electrically connected to said second diffused region.

2. The semiconductor device according to claim 1, wherein said gate electrode and said first, second and fourth diffused regions have surfaces silicided with a mask of mask material covering at least said third diffused region.

3. The semiconductor device according to claim 1, further comprising a sidewall insulator formed on a sidewall of said gate electrode.

4. The semiconductor device according to claim 1, wherein said second diffused region is short-circuited with said semiconductor region.

5. The semiconductor device according to claim 1, further comprising:
a contact region formed in said surface of said semiconductor region and having the same conduction type as that of said semiconductor region; and
a wire arranged to short-circuit between said contact region and said second diffused region.

6. The semiconductor device according to claim 1, wherein said third diffused region is provided per a plurality of insulated-gate semiconductor elements each including said first and second diffused regions and said gate electrode.

7. The semiconductor device according to claim 1, further comprising:
a fifth diffused region formed in said surface of said semiconductor region at a distant from said first diffused region; and
a wire arranged to connect said first diffused region with said fifth diffused region,
wherein said third diffused region is electrically connected through said fifth diffused region to said first diffused region.

8. The semiconductor device according to claim 7, wherein said gate electrode and said first, second, fourth and fifth diffused regions have surfaces silicided with a mask of mask material formed on at least said third diffused region.

9. The semiconductor device according to claim 7, further comprising a sidewall insulator formed on a sidewall of said gate electrode.

10. The semiconductor device according to claim 7, wherein said second diffused region is short-circuited with said semiconductor region.

11. The semiconductor device according to claim 10, further comprising:
a contact region formed in said surface of said semiconductor region and having the same conduction type as that of said semiconductor region; and
a wire arranged to short-circuit between said contact region and said second diffused region.

12. The semiconductor device according to claim 7, wherein said fourth diffused region is formed in the shape of a stripe in said surface of said semiconductor region,
wherein said third, fifth, first and second diffused regions are formed symmetrically on both left and right sides of said fourth diffused region.

13. The semiconductor device according to claim 7, wherein said third diffused region is provided per a plurality of insulated-gate semiconductor elements each including said first and second diffused regions and said gate electrode.
